(19) United States
(12) Patent Application Publication
(10) Pub. No.: US 2025/0301786 A1
(43) Pub. Date: Sep. 25, 2025

(54) SEMICONDUCTOR DEVICE

(71) Applicant: Samsung Electronics Co., Ltd., Suwon-si (KR)

(72) Inventors: Jinchan Yun, Suwon-si (KR); Dahye Kim, Suwon-si (KR); Jae Hyun Park, Suwon-si (KR); Daihong Huh, Suwon-si (KR)

(21) Appl. No.: 19/032,554

(22) Filed: Jan. 21, 2025

(30) Foreign Application Priority Data
Mar. 22, 2024 (KR) 10-2024-0040000

(51) Int. Cl. H10D 84/85; H10D 84/01

(52) U.S. Cl. CPC H10D 84/856; H10D 84/0167; H10D 84/017; H10D 84/0186; H10D 84/851

(57) ABSTRACT

Disclosed is a semiconductor device comprising a first channel structure extending in a first direction, a second channel structure adjacent in a second direction to the first channel structure, a source/drain structure between the first and second channel structures including lower and upper source/drain patterns, and a lower contact that is in contact with the lower source/drain pattern. The lower source/drain pattern includes a first semiconductor layer and a second semiconductor layer in contact therewith. The first semiconductor layer has a sidewall in contact with the second semiconductor layer, a contact surface in contact with the lower contact, and a bottom surface that extends from the sidewall to the contact surface. The sidewall of the first semiconductor layer includes a first portion in contact with the second semiconductor layer, and a second portion spaced apart from the second semiconductor layer.

### CROSS-REFERENCE TO RELATED APPLICATION

This U.S. nonprovisional application claims priority under 35 U.S.C § 119 to Korean Patent Application No. 10-2024-0040000 filed on Mar. 22, 2024 in the Korean Intellectual Property Office, the disclosure of which is hereby incorporated by reference in its entirety.

### BACKGROUND

The present inventive concepts relate to a semiconductor device, and more particularly, to a semiconductor device including a lower source/drain pattern.

A semiconductor device includes an integrated circuit including metal oxide semiconductor field effect transistors (MOSFETs). As sizes and design rules of the semiconductor device are gradually decreased, sizes of the MOSFETs are also increasingly scaled down. The scale down of MOSFETs may deteriorate operating characteristics of the semiconductor device. Accordingly, various studies have been conducted to develop methods of fabricating semiconductor devices having superior performances while overcoming limitations caused by high integration of the semiconductor devices.

### SUMMARY

Some embodiments of the present inventive concepts provide a semiconductor device improved electrical properties and increased reliability.

According to some embodiments of the present inventive concepts, a semiconductor device may comprise a first channel structure that extends in a first direction, a second channel structure that extends in the first direction and is adjacent in a second direction to the first channel structure, the second direction intersecting the first direction, a source/drain structure between the first channel structure and the second channel structure, wherein the source/drain structure includes a lower source/drain pattern and an upper source/drain pattern that overlaps in a third direction with the lower source/drain pattern, the third direction intersecting the first direction and the second direction, and a lower contact that is in contact with the lower source/drain pattern. The lower source/drain pattern may include a first semiconductor layer, and a second semiconductor layer in contact with the first semiconductor layer. The first semiconductor layer may include a sidewall in contact with the second semiconductor layer, a contact surface that is in contact with the lower contact, and a bottom surface that extends from the sidewall to the contact surface. The sidewall of the first semiconductor layer may include a first portion in contact with the second semiconductor layer, and a second portion spaced apart in the third direction from the second semiconductor layer.

According to some embodiments of the present inventive concepts, a semiconductor device may comprise a first channel structure that extends in a first direction, a second channel structure that extends in the first direction and is adjacent in a second direction to the first channel structure, the second direction intersecting the first direction, a source/drain structure between the first channel structure and the second channel structure, wherein the source/drain structure includes a lower source/drain pattern and an upper source/drain pattern that overlaps in a third direction with the lower source/drain pattern, the third direction intersecting the first direction and the second direction, and a lower contact that is in contact with the lower source/drain pattern. The lower source/drain pattern may include a first semiconductor layer, and a second semiconductor layer that is in contact with the first semiconductor layer. A distance from a lowermost portion of the first semiconductor layer to an upper surface of the lower source/drain pattern is greater than a distance from a lowermost portion of the second semiconductor layer to the upper surface of the lower source/drain pattern.

According to some embodiments of the present inventive concepts, a semiconductor device may comprise a lower dielectric layer, a first channel structure that extends in a first direction on the lower dielectric layer, a second channel structure that extends in the first direction and is adjacent in a second direction to the first channel structure, the second direction intersecting the first direction, a first gate electrode that overlaps in a third direction with the first channel structure, the third direction intersecting the first direction and the second direction, a second gate electrode that overlaps in the third direction with the second channel structure, a lower source/drain pattern between the first channel structure and the second channel structure, an upper source/drain pattern that overlaps in the third direction with the lower source/drain pattern, a lower contact that extends into the lower dielectric layer electrically connect to the lower source/drain pattern, and an upper contact electrically connected to the upper source/drain pattern. The lower source/drain pattern may include a first semiconductor layer, and a second semiconductor layer in contact with the first semiconductor layer. The first semiconductor layer may include an upper pattern in contact with the second semiconductor layer, and a lower pattern in contact with the lower contact. The lower pattern of the first semiconductor layer may be spaced apart in the third direction from the second semiconductor layer and between the upper pattern and the lower contact.

### BRIEF DESCRIPTION OF DRAWINGS

FIG. 1 illustrates a conceptual diagram showing a logic cell of a semiconductor device according to some embodiments.

FIG. 2 illustrates a conceptual diagram showing a logic cell of a semiconductor device according to some embodiments.

FIG. 3 illustrates a plan view showing a semiconductor device according to some embodiments.

FIG. 4 illustrates a cross-sectional view taken along line A-A′ of FIG. 3.

FIG. 5 illustrates a cross-sectional view taken along line B-B′ of FIG. 3.

FIG. 6 illustrates an enlarged view showing section E of FIG. 4.

FIGS. 7A, 7B, 7C, 7D, 7E, 7F, 7G, 7H, 7I, 7J, and 7K illustrate cross-sectional views showing a method of fabricating a semiconductor device according to some embodiments.

### DETAILED DESCRIPTION OF EMBODIMENTS

It will be hereinafter discussed a semiconductor device and a method of fabricating the same according to some embodiments of the present inventive concept in conjunction with the accompanying drawings.

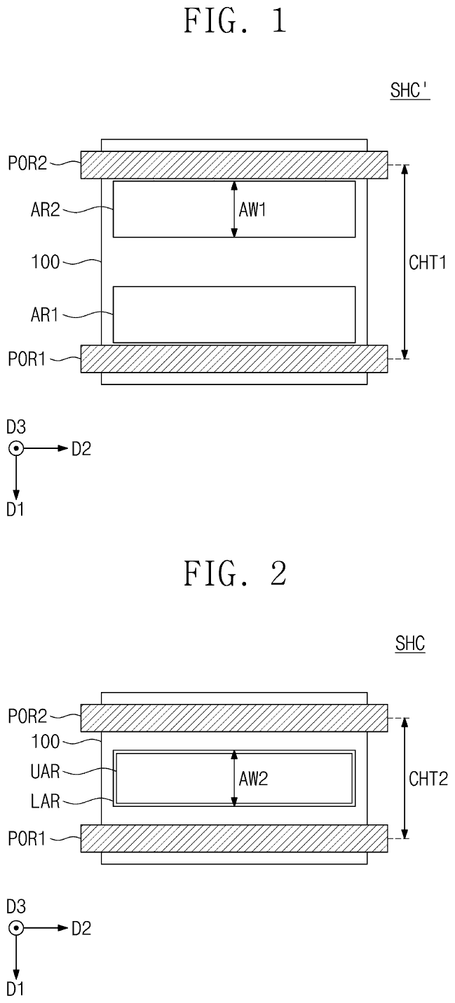

FIG. 1 illustrates a conceptual diagram showing a logic cell of a semiconductor device according to some embodiments.

Referring to FIG. 1, a single height cell SHC′ may be provided. For example, a substrate 100 may be provided thereon with a first power line POR1 and a second power line POR2. One of the first power line POR1 and the second power line POR2 may be provided with a drain voltage (VDD) or a power voltage. The other of the first power line POR1 and the second power line POR2 may be provided with a source voltage (VSS) or a ground voltage. The first power line POR1 and the second power line POR2 may be spaced apart from each other in a first direction D1. Each of the first power line POR1 and the second power line POR2 may extend along a second direction D2. The first direction D1 and the second direction D2 may intersect each other. For example, the first direction D1 and the second direction D2 may be horizontal directions that are orthogonal to each other.

The single height cell SHC′ may be defined between the first power line POR1 and the second power line POR2. The single height cell SHC′ may include a first active region AR1 and a second active region AR2. One of the first active region AR1 and the second active region AR2 may be a PMOSFET region, and the other of the first active region AR1 and the second active region AR2 may be an NMOSFET region. For example, the single height cell SHC′ may have a complementary metal oxide semiconductor (CMOS) structure provided between the first power line POR1 and the second power line POR2.

A semiconductor device according to the present comparative example may be a two-dimensional device in which transistors of front-end-of-line (FEOL) layer are arranged two-dimensionally. For example, an NMOSFET of the first active region AR1 and a PMOSFET of the second active region AR2 may be disposed spaced apart from each other in the first direction D1.

Each of the first active region AR1 and the second active region AR2 may have a first width AW1 in the first direction D1. A first height CHT1 may be defined to refer to a length in the first direction D1 of the single height cell SHC′ according to the present comparative example. The first height CHT1 may be substantially the same as a distance (e.g., pitch) between the first power line POR1 and the second power line POR2.

The single height cell SHC′ may constitute a single logic cell. In this description, the logic cell may mean a logic device (e.g., AND, OR, XOR, XNOR, and inverter) that performs a specific function. For example, the logic cell may include transistors for constituting a logic device, and may also include wiring lines that connect the transistors to each other.

As a two-dimensional device is included in the single height cell SHC′ according to the present comparative example, the first active region AR1 and the second active region AR2 may be spaced apart from each other in the first direction D1 without vertically overlapping each other. Therefore, it may be that the first height CHT1 of the single height cell SHC′ be defined to encompass all of the first and second active regions AR1 and AR2 that are spaced apart from each other in the first direction D1. For example, the first height CHT1 of the single height cell SHC′ may have a size enough to encompass at least two first widths AW1. As a result, the first height CHT1 of the single height cell SHC′ according to the present comparative example may be relatively greater than a second height CHT2 of a single height cell SHC which will be discussed below. Therefore, the single height cell SHC′ according to the present comparative example may have a relatively large area.

FIG. 2 illustrates a conceptual diagram showing a logic cell of a semiconductor device according to some embodiments.

Referring to FIG. 2, a single height cell SHC may be provided which includes a three-dimensional device such as a stacked transistor. For example, a substrate 100 may be provided thereon with a first power line POR1 and a second power line POR2. The single height cell SHC may be defined between the first power line POR1 and the second power line POR2.

The single height cell SHC may include a lower active region LAR and an upper active region UAR. One of the lower active region LAR and the upper active region UAR may be a PMOSFET region, and the other of the lower active region LAR and the upper active region UAR may be an NMOSFET region.

A semiconductor device according to the present embodiment may be a three-dimensional device, and transistors of a front-end-of-line (FEOL) layer may be vertically stacked. The substrate 100 may be provided thereon with the lower active region LAR as a bottom tier, and the lower active region LAR may be provided thereon with the upper active region UAR as a top tier. For example, a PMOSFET of the lower active region LAR may be provided on the substrate 100, and an NMOSFET of the upper active region UAR may be stacked on the PMOSFET. The lower active region LAR and the upper active region UAR may be spaced apart from each other in a vertical direction or a third direction D3. The third direction D3 may intersect the first direction D1 and the second direction D2. For example, the third direction D3 may be a vertical direction perpendicular to the first direction D1 and the second direction D2.

Each of the lower active region LAR and the upper active region UAR may have a second width AW2 in the first direction D1. A second height CHT2 may be defined to refer to a length in the first direction D1 of the single height cell SHC according to the present embodiment.

As the single height cell SHC according to the present embodiment includes a three-dimensional device or a stacked transistor, the lower active region LAR and the upper active region UAR may vertically overlap each other. Therefore, the second height CHT2 of the single height cell SHC may have a size enough to encompass one second width AW2. As a result, the second height CHT2 of the single height cell SHC according to the present embodiment may be less than the first height CHT1 of the single height cell SHC′ discussed above in FIG. 1. For example, the single height cell SHC according to the present embodiment may have a relatively small area. In a three-dimensional semiconductor device according to the present embodiment, an area of the logic cell may be reduced to increase integration of the device.

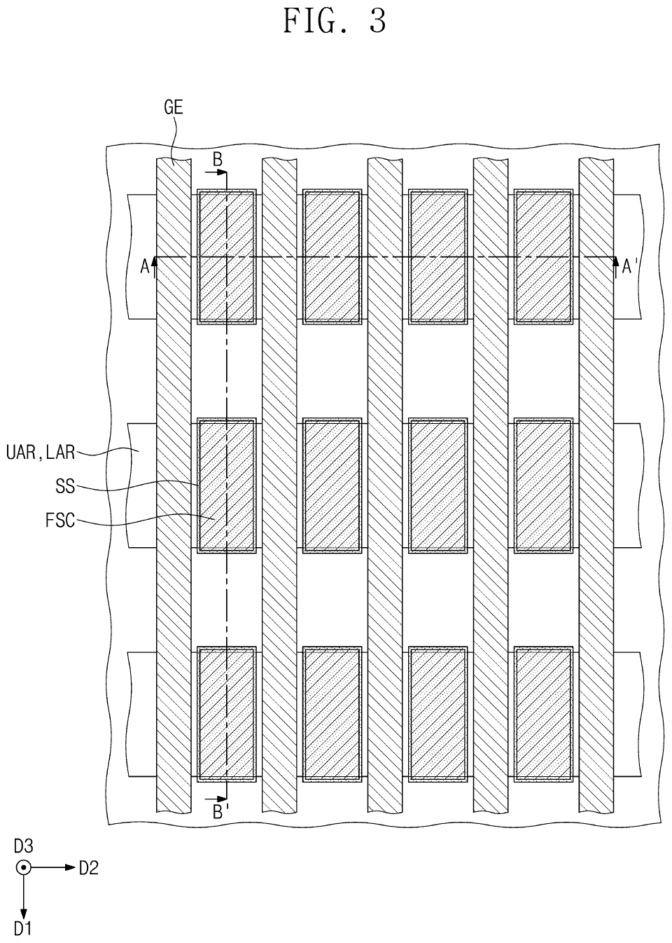

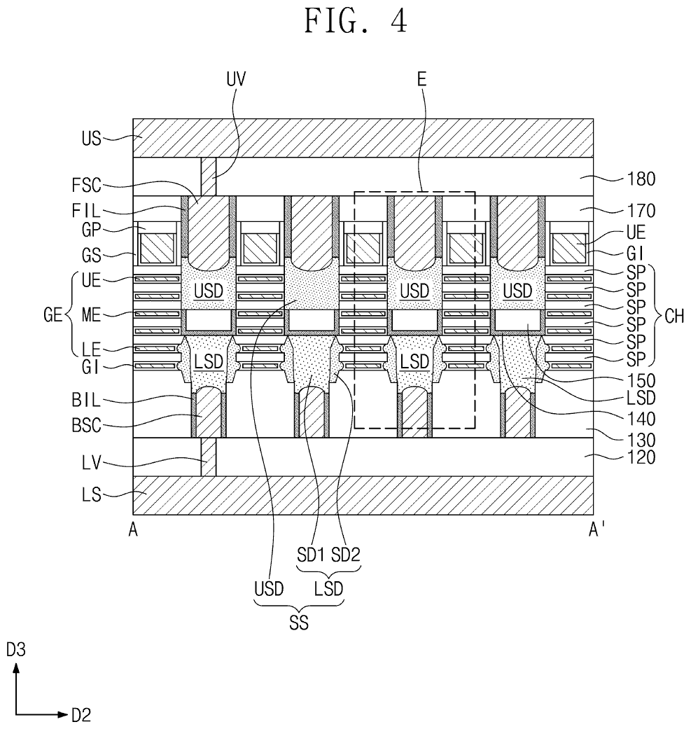

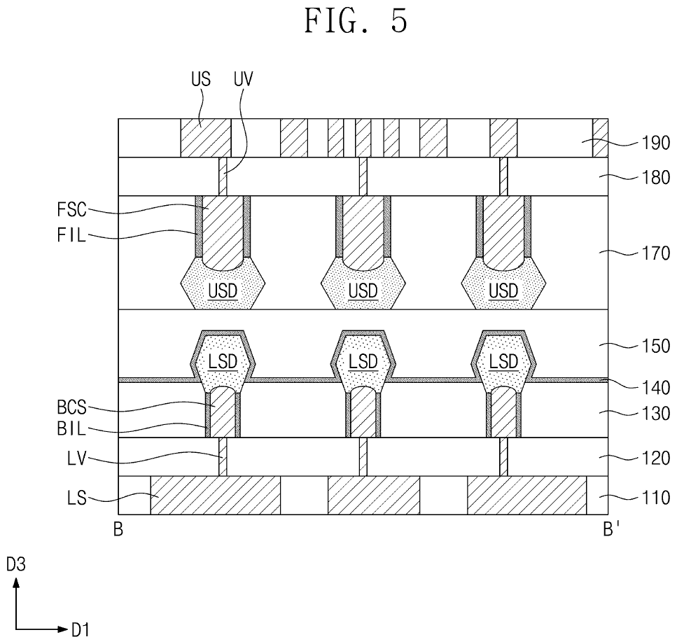

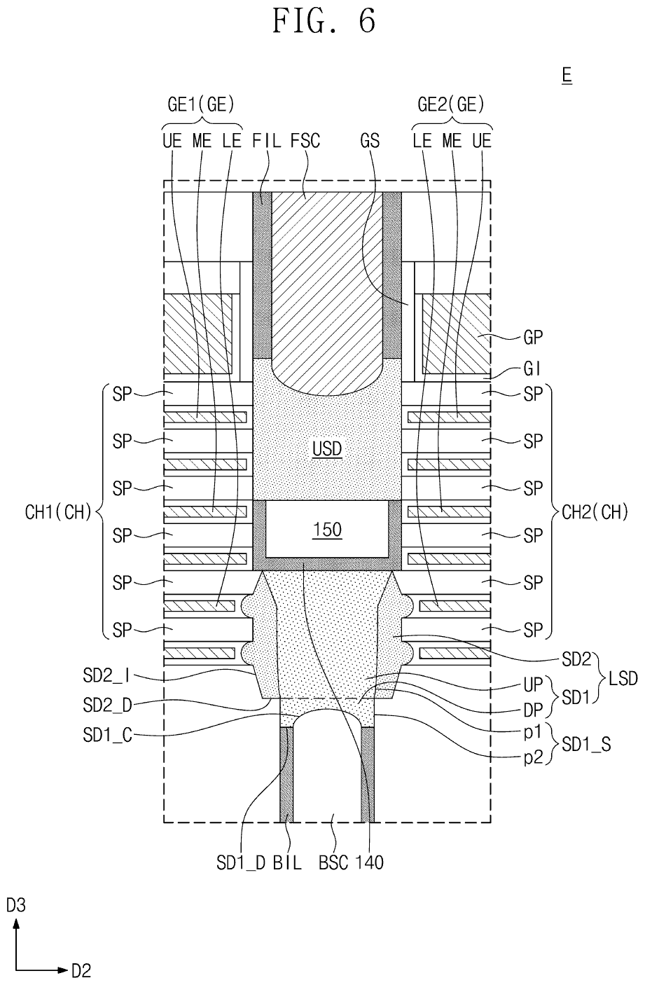

FIG. 3 illustrates a plan view showing a semiconductor device according to some embodiments. FIG. 4 illustrates a cross-sectional view taken along line A-A′ of FIG. 3. FIG. 5 illustrates a cross-sectional view taken along line B-B′ of FIG. 3. FIG. 6 illustrates an enlarged view showing section E of FIG. 4.

Referring to FIGS. 3 to 6, a first lower dielectric layer 110, a second lower dielectric layer 120, and a third lower dielectric layer 130 may be provided. The second lower dielectric layer 120 may be disposed on the first lower dielectric layer 110. The third lower dielectric layer 130 may be disposed on the second lower dielectric layer 120. The first, second, and third lower dielectric layers 110, 120, and 130 may include a dielectric material. For example, the first, second, and third lower dielectric layers 110, 120, and 130 may include oxide.

A plurality of channel structures CH may be provided on the third lower dielectric layer 130. The plurality of channel structures CH may be spaced apart from each other in a second direction D2. Each of the channel structures CH may include semiconductor patterns SP that overlap each other in a third direction D3. The number of the semiconductor patterns SP is not limited to that shown. For example, the number of the semiconductor patterns SP may be five or less, or seven or more. The semiconductor pattern SP may include crystalline silicon. The semiconductor pattern SP may be a nano-sheet. In some embodiments, the semiconductor pattern SP may include silicon (Si), germanium (Ge), or silicon-germanium (SiGe).

A plurality of gate electrodes GE may be provided on the third lower dielectric layer 130. The gate electrode GE may overlap in the third direction D3 with the semiconductor patterns SP of one channel structure CH. The plurality of gate electrodes GE may be spaced apart from each other in the second direction D2. The gate electrode GE may include a portion interposed between the semiconductor patterns SP that overlap each other in the third direction D3.

Each of the gate electrodes GE may include a lower electrode LE, a middle electrode ME, and an upper electrode UE. The middle electrode ME may be disposed on the lower electrode LE. The upper electrode UE may be disposed on the middle electrode ME. The lower electrode LE, the middle electrode ME, and the upper electrode UE of one gate electrode GE may overlap in the third direction D3. The lower electrode LE, the middle electrode ME, and the upper electrode UE of one gate electrode GE may be connected to each other. In some embodiments, the lower electrode LE, the middle electrode ME, and the upper electrode UE may include different conductive materials from each other.

Gate dielectric layers GI may be provided. The gate dielectric layer GI may separate the gate electrode GE from the semiconductor pattern SP. The gate dielectric layer GI may cover, overlap, or be on a top surface, a bottom surface, and a sidewall of the semiconductor pattern SP. The gate dielectric layer GI may include a dielectric material. For example, the gate dielectric layer GI may include oxide.

Gate spacers GS may be provided. A pair of gate spacers GS may be disposed on opposite sidewalls of the gate electrode GE. The gate spacer GS may extend in the first direction D1. The gate spacer GS may have a top surface higher than that of the gate electrode GE. The gate spacer GS may include a dielectric material.

Gate capping patterns GP may be provided. The gate capping pattern GP may be provided on the gate electrode GE. The gate capping pattern GP may extend in the first direction D1. A top surface of the gate capping pattern GP may be coplanar with the top surface of the gate spacer GS. The gate capping pattern GP may include a dielectric material. For example, the gate capping pattern GP may include nitride.

Source/drain structures SS may be provided. The source/drain structure SS may be provided between a pair of gate electrodes GE that are adjacent to each other in the second direction D2. The source/drain structures SS may be spaced apart from each other in the second direction D2. The source/drain structures SS and the gate electrodes GE may be disposed alternately with each other in the second direction D2. The source/drain structure SS may be disposed between the semiconductor patterns SP that are adjacent to each other in the second direction D2. The source/drain structure SS may be in contact with the semiconductor patterns SP.

Each of the source/drain structures SS may include a lower source/drain pattern LSD and an upper source/drain pattern USD. The lower source/drain pattern LSD and the upper source/drain pattern USD that are included in one source/drain structure SS may overlap each other in the third direction D3. The lower source/drain pattern LSD and the upper source/drain pattern USD may be epitaxial patterns formed by a selective epitaxial growth process. The lower source/drain pattern LSD and the upper source/drain pattern USD may include a semiconductor material. For example, the lower source/drain pattern LSD may have a p-type conductivity, and the upper source/drain pattern USD may have an n-type conductivity. In some embodiments, the lower source/drain pattern LSD may have an n-type conductivity, and the upper source/drain pattern USD may have a p-type conductivity

The lower source/drain pattern LSD may include a first semiconductor layer SD1 and a second semiconductor layer SD2. The first semiconductor layer SD1 may be spaced apart from the semiconductor pattern SP. The second semiconductor layer SD2 may be in contact with the semiconductor pattern SP. The second semiconductor layer SD2 may surround the first semiconductor layer SD1. The first semiconductor layer SD1 may include a first semiconductor material, and the second semiconductor layer SD2 may include a second semiconductor material. For example, the first and second semiconductor materials of the first and second semiconductor layers SD1 and SD2 may include silicon-germanium (SiGe). The semiconductor material of the second semiconductor layer SD2 may have a different concentration from that of the second semiconductor material of the second semiconductor layer SD2. For example, a concentration of germanium (Ge) included in the second semiconductor material may be less than a concentration of germanium (Ge) included in the first semiconductor material.

Lower contracts BSC may be provided. The lower contact BSC may penetrate or extend into the third lower dielectric layer 130 to come into contact with a lower portion of the first semiconductor layer SD1 of the lower source/drain pattern LSD. The lower contact BSC may include a conductive material. For example, the lower contact BSC may include metal.

Lower contact dielectric layers BIL may be provided. The lower contact dielectric layer BIL may surround the lower contact BSC. The lower contact dielectric layer BIL may be disposed between the lower contact BSC and the third lower dielectric layer 130. The lower contact dielectric layer BIL may include a dielectric material.

Lower vias LV and lower signal lines LS may be provided. The lower via LV may penetrate or extend into the second lower dielectric layer 120 to come into contact with the lower contact BSC. The lower signal lines LS may be spaced apart from each other along the first direction D1. The lower signal line LS may extend in the second direction D2. The lower source/drain pattern LSD may be electrically connected to the lower signal line LS through the lower contact BSC and the lower via LV. The lower via LV and the lower signal line LS may include a conductive material.

A first interlayer dielectric layer 140 and a second interlayer dielectric layer 150 may be provided. The first interlayer dielectric layer 140 may be provided on the lower source/drain pattern LSD. The second interlayer dielectric layer 150 may be provided on the first interlayer dielectric layer 140. A portion of the first interlayer dielectric layer 140 and a portion of the second interlayer dielectric layer 150 may be interposed between the lower source/drain pattern LSD and the upper source/drain pattern USD. The first and second interlayer dielectric layers 140 and 150 may include a dielectric material. For example, the first interlayer dielectric layer 140 may include nitride, and the second interlayer dielectric layer 150 may include oxide.

A first upper dielectric layer 170, a second upper dielectric layer 180, and a third upper dielectric layer 190 may be provided. The first upper dielectric layer 170 may be provided on the second interlayer dielectric layer 150. The second upper dielectric layer 180 may be provided on the first upper dielectric layer 170. The third upper dielectric layer 190 may be provided on the second upper dielectric layer 180. The first, second, and third upper dielectric layers 170, 180, and 190 may include a dielectric material.

Upper contacts FSC may be provided. The upper contact FSC may penetrate or extend into the first upper dielectric layer 170 to come into contact with an upper portion of the upper source/drain pattern USD. The upper contact FSC may include a conductive material. For example, the upper contact FSC may include metal.

Upper contact dielectric layers FIL may be provided. The upper contact dielectric layer FIL may surround the upper contact FSC in plan view. The upper contact dielectric layer FIL may be disposed between the upper contact FSC and the first upper dielectric layer 170. The upper contact dielectric layer FIL may include a dielectric material.

Upper vias UV and upper signal lines US may be provided. The upper via UV may penetrate or extend into the second upper dielectric layer 180 to come into contact with the upper contact FSC. The upper signal lines US may be spaced apart from each other along the first direction D1. The upper signal line US may extend in the second direction D2. The upper source/drain pattern USD may be electrically connected to the upper signal line US through the upper contact FSC and the upper via UV. The upper via UV and the upper signal line US may include a conductive material.

Referring back to FIG. 6, the channel structures CH may include a first channel structure CH1 and a second channel structure CH2. The first channel structure CH1 and the second channel structure CH2 may be spaced apart from each other across the source/drain structure SS. The first channel structure CH1 and the second channel structure CH2 may be adjacent to each other in the second direction D2.

The gate electrodes GE may include a first gate electrode GE1 and a second gate electrode GE2. The first gate electrode GE1 and the second gate electrode GE2 may be spaced apart from each other across the source/drain structure SS. The first gate electrode GE1 may overlap in the third direction D3 with the first channel structure CH1. The second gate electrode GE2 may overlap in the third direction D3 with the second channel structure CH2.

The first semiconductor layer SD1 of the lower source/drain pattern LSD may have a sidewall SD1_S, a bottom surface SD1_D, and a contact surface SD1_C. The sidewall SD1_S of the first semiconductor layer SD1 may be in contact with the second semiconductor layer SD2 and the third lower dielectric layer 130. The bottom surface SD1_D of the first semiconductor layer SD1 may connect the sidewall SD1_S of the first semiconductor layer SD1 to the contact surface SD1_C of the first semiconductor layer SD1. The first semiconductor layer SD1 may be flat on the bottom surface SD1_D. In some embodiments, the first semiconductor layer SD1 may be curved on the bottom surface SD1_D. The bottom surface SD1_D of the first semiconductor layer SD1 may be in contact with the lower contact dielectric layer BIL. The contact surface SD1_C of the first semiconductor layer SD1 may be in contact with the lower contact BSC. The first semiconductor layer SD1 may be curved on the contact surface SD1_C. The contact surface SD1_C of the first semiconductor layer SD1 may be concave toward the upper source/drain pattern USD.

The sidewall SD1_S of the first semiconductor layer SD1 may include a first portion p1 and a second portion p2. The first portion pl of the sidewall SD1_S of the first semiconductor layer SD1 may be in contact with the third lower dielectric layer 130. The first portion pl of the sidewall SD1_S of the first semiconductor layer SD1 may be spaced apart from the second semiconductor layer SD2. The second portion p2 of the sidewall SD1_S of the first semiconductor layer SD1 may be in contact with the second semiconductor layer SD2. The second portion p2 of the sidewall SD1_S of the first semiconductor layer SD1 may be spaced apart from the third lower dielectric layer 130.

The first semiconductor layer SD1 of the lower source/drain pattern LSD may include a lower pattern DP and an upper pattern UP on the lower pattern DP. The lower pattern DP of the first semiconductor layer SD1 may be spaced apart from the second semiconductor layer SD2. The lower pattern DP of the first semiconductor layer SD1 may be in contact with the third lower dielectric layer 130, the lower contact BSC, and the lower contact dielectric layer BIL. The lower pattern DP of the first semiconductor layer SD1 may be disposed between the lower contact BSC and the upper pattern UP of the first semiconductor layer SD1. The upper pattern UP of the first semiconductor layer SD1 may be spaced apart from the third lower dielectric layer 130, the lower contact BSC, and the lower contact dielectric layer BIL. The upper pattern UP of the first semiconductor layer SD1 may be in contact with the second semiconductor layer SD2 and the first interlayer dielectric layer 140.

The second semiconductor layer SD2 of the lower source/drain pattern LSD may have a bottom surface SD2_D and an inclined surface SD2_I. The bottom surface SD2_D and the inclined surface SD2_I of the second semiconductor layer SD2 may be in contact with the third lower dielectric layer 130. The second semiconductor layer SD2 may be flat on the bottom surface SD2_D and the inclined surface SD2_I. For example, the bottom surface SD2_D of the second semiconductor layer SD2 may be parallel to the second direction D2, and the inclined surface SD2_I of the second semiconductor layer SD2 may be oblique to the bottom surface SD2_D of the second semiconductor layer SD2.

A lowermost portion of the first semiconductor layer SD1 may be at a level lower than that of a lowermost portion of the second semiconductor layer SD2. The level of the lowermost portion of the first semiconductor layer SD1 may be lower than that of an uppermost portion of the lower contact BSC. The level of the lowermost portion of the first semiconductor layer SD1 may be lower than that of a lowermost portion of the gate dielectric layer GI.

The level of the uppermost portion of the lower contact BSC may be lower than that of the lowermost portion of the second semiconductor layer SD2. The level of the uppermost portion of the lower contact BSC may be lower than that of the bottom surface SD2_D of the second semiconductor layer SD2. The level of the uppermost portion of the lower contact BSC may be lower than that of the lowermost portion of the gate dielectric layer GI. The level of the uppermost portion of the lower contact BSC may be higher than that of the bottom surface SD1_D of the first semiconductor layer SD1.

The level of the bottom surface SD2_D of the second semiconductor layer SD2 may be higher than that of the bottom surface SD1_D of the first semiconductor layer SD1. The level of the bottom surface SD2_D of the second semiconductor layer SD2 may be higher than that of the contact surface SD1_C of the first semiconductor layer SD1. The level of the bottom surface SD2_D of the second semiconductor layer SD2 may be lower than that of the lowermost portion of the gate dielectric layer GI.

The lower pattern DP of the first semiconductor layer SD1 may be at a level lower than that of the upper pattern UP of the first semiconductor layer SD1. The level of the lower pattern DP of the first semiconductor layer SD1 may be lower than that of the lowermost portion of the gate dielectric layer GI.

A minimum distance between the contact surface SD1_C and a top surface of the first semiconductor layer SD1 may increase as a level decreases. The minimum distance between the contact surface SD1_C and the top surface of the first semiconductor layer SD1 may be less than a minimum distance between the bottom surface SD1_D and the top surface of the first semiconductor layer SD1. A distance between the top surface of the first semiconductor layer SD1 and a lowermost portion of the first semiconductor layer SD1 may be greater than a distance between the bottom surface SD2_D and an uppermost portion of the second semiconductor layer SD2.

The lower source/drain pattern LSD of a semiconductor device according to some embodiments may include the first semiconductor layer SD1 that vertically extends. It may thus be possible to omit the formation of a spacer in the procedure for forming the lower source/drain pattern LSD. Accordingly, there may be a reduction in the difficulty and number of process steps in fabricating a semiconductor device.

The lower source/drain pattern LSD of a semiconductor device according to some embodiments may include the first semiconductor layer SD1 that vertically extends. Therefore, a volume of the lower source/drain pattern LSD may increase to improve electrical properties of the semiconductor device.

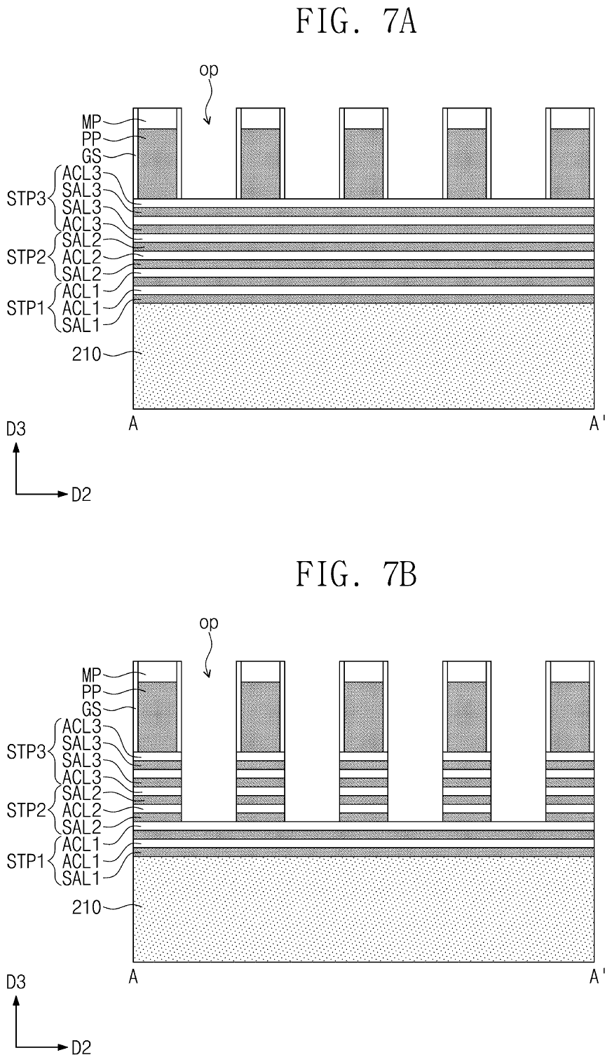

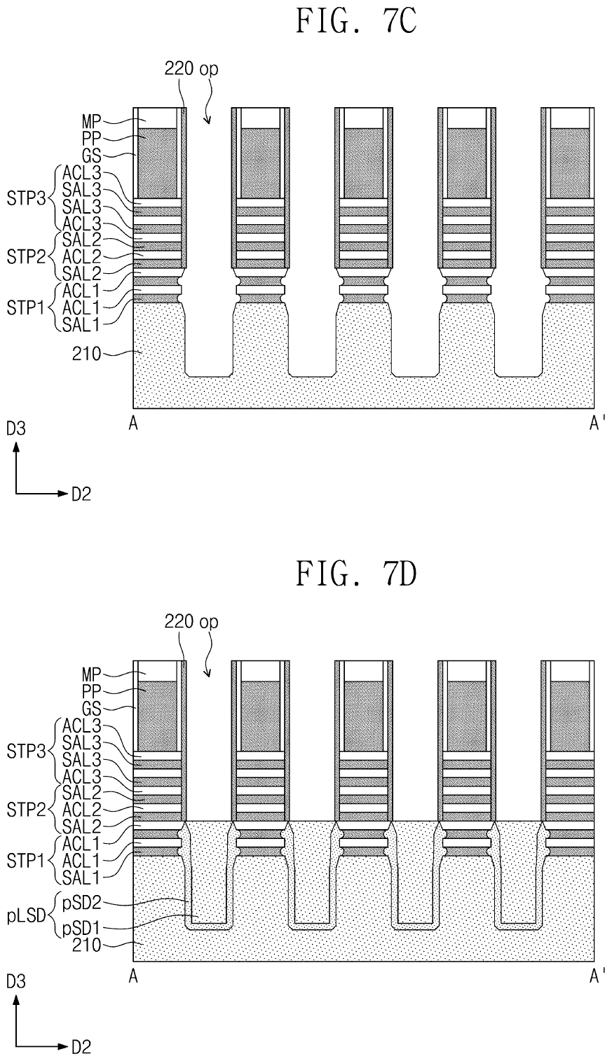

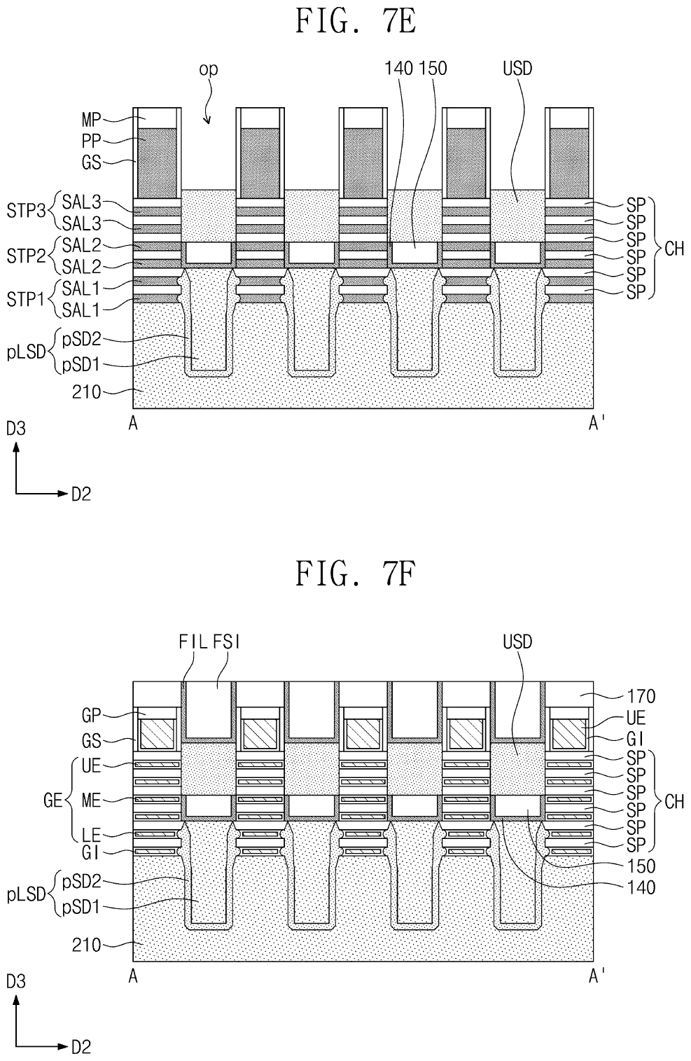

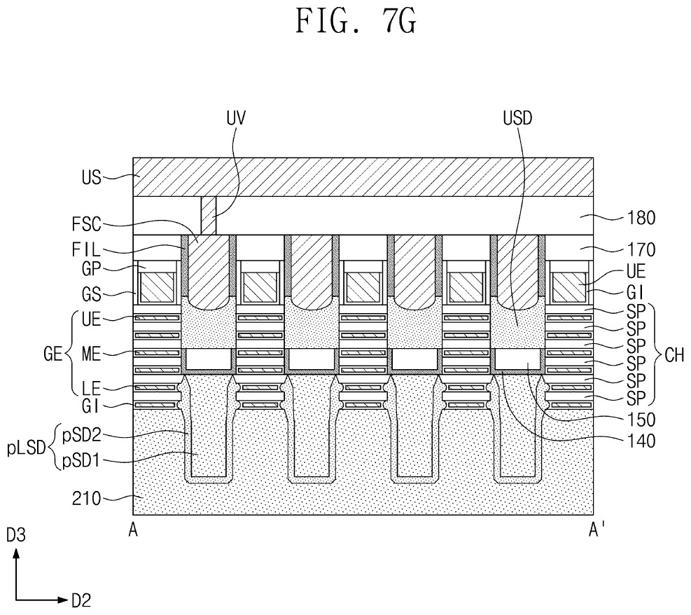

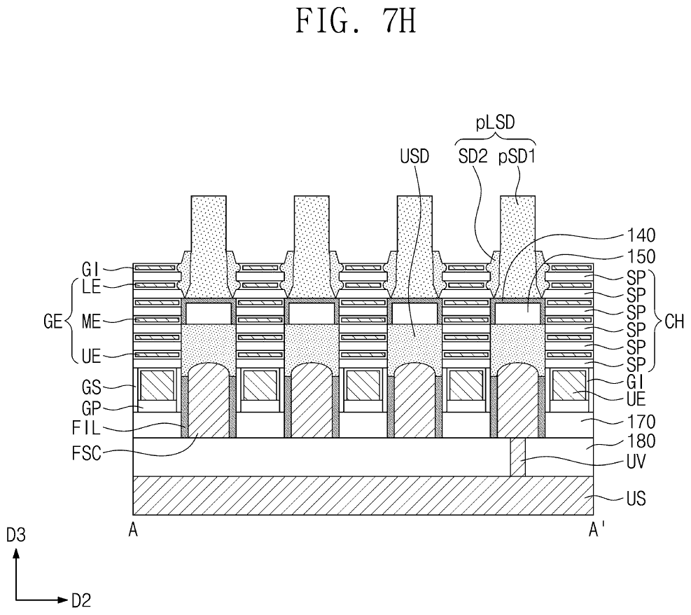

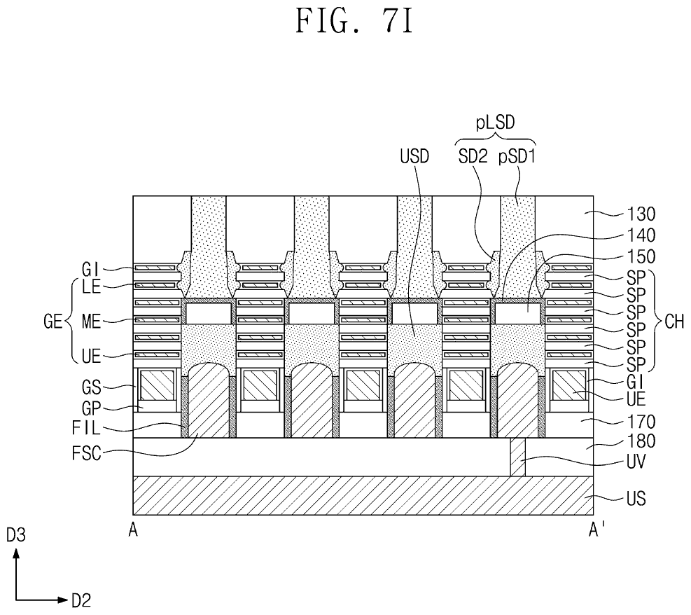

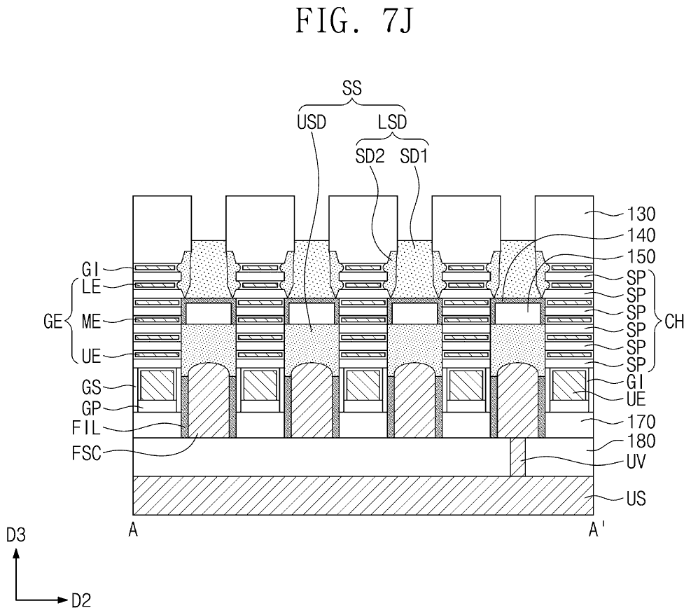

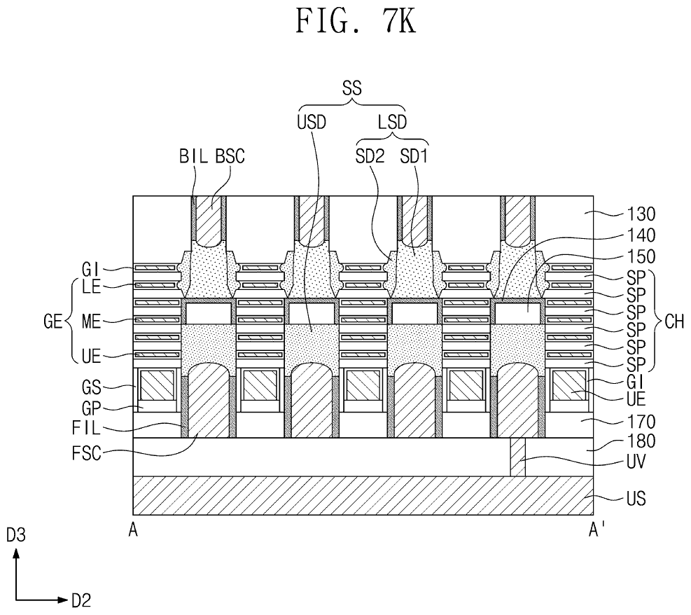

FIGS. 7A, 7B, 7C, 7D, 7E, 7F, 7G, 7H, 7I, 7J, and 7K illustrate cross-sectional views showing a method of fabricating a semiconductor device according to some embodiments. FIGS. 7A, 7B, 7C, 7D, 7E, 7F, 7G, 7H, 7I, 7J, and 7K may correspond to FIG. 4.

Referring to FIG. 7A, a substrate 210 may be provided. The substrate 210 may be a semiconductor substrate, a dielectric substrate, a silicon-on-insulator (SOI) substrate, or a germanium-on-insulator (GOI) substrate. For example, the semiconductor substrate may include silicon, germanium, silicon-germanium, gallium phosphide (GaP), or gallium arsenide (GaAs).

A first stack pattern STP1 may be formed on the substrate 210. The first stack pattern STP1 may be formed on a top surface of the substrate 210. The first stack pattern STP1 may include first sacrificial layers SAL1 and first active layers ACL1. The first sacrificial layers SAL1 and the first active layers ACL1 may be alternately stacked on the substrate 210. The first sacrificial layers SAL1 may include one of silicon (Si), germanium (Ge), and silicon-germanium (SiGe), and the first active layers ACL1 may include another of silicon (Si), germanium (Ge), and silicon-germanium (SiGe). For example, the first sacrificial layers SAL1 may include silicon-germanium (SiGe), and the first active layers ACL1 may include silicon (Si).

A second stack pattern STP2 may be formed on the first stack pattern STP1. The second stack pattern STP2 may include second sacrificial layers SAL2 and second active layers ACL2. The second sacrificial layers SAL2 and the second active layers ACL2 may be alternately stacked on the first stack pattern STP1. Each of the second sacrificial layers SAL2 may include the same material as that of the first sacrificial layer SAL1, and each of the second active layers ACL2 may include the same material as that of the first active layer ACL1.

A third stack pattern STP3 may be formed on the second stack pattern STP2. The third stack pattern STP3 may include third sacrificial layers SAL3 and third active layers ACL3. The third sacrificial layers SAL3 and the third active layers ACL3 may be alternately stacked on the second stack pattern STP2. Each of the third sacrificial layers SAL3 may include the same material as that of the first sacrificial layer SAL1, and each of the third active layers ACL3 may include the same material as that of the first active layer ACL1.

The first, second, and third stack patterns STP1, STP2, and STP3 may be formed by patterning conductive layers and dielectric layers. The formation of the first, second, and third stack patterns STP1, STP2, and STP3 may include forming a hardmask pattern on an uppermost third active layer ACL3, and using the hardmask pattern as an etching mask to etch the conductive layers and the dielectric layers stacked on the substrate 210.

A plurality of sacrificial patterns PP may be formed which run across the first, second, and third stack patterns STP1, STP2, and STP3. Each of the sacrificial patterns PP may be formed to have a linear shape that extends in a first direction D1. For example, the formation of the sacrificial patterns PP may include forming a sacrificial layer on a front surface of the substrate 210, forming a hardmask pattern MP on the sacrificial layer, and using the hardmask pattern MP as an etching mask to pattern the sacrificial layer. The sacrificial layer may include one or more of amorphous silicon and polysilicon.

A pair of gate spacers GS may be formed on opposite sidewalls of the sacrificial pattern PP. For example, a spacer layer may be conformally formed on the front surface of the substrate 210. The spacer layer may cover or overlap the sacrificial pattern PP and the hardmask pattern MP. For example, the spacer layer may include at least one selected from SiCN, SiCON, and/or SiN. The spacer layer may be anisotropically etched to form the gate spacers GS. The spacer layer may be etched to form an opening op. The opening op may expose sidewalls of the gate spacers GS and a top surface of an uppermost third active layer ACL3. The opening op may be defined by the exposed sidewalls of the gate spacers GS and the exposed top surface of the uppermost third active layer ACL3. The opening op may be provided between the sacrificial patterns PP that are adjacent to each other.

Referring to FIG. 7B, the gate spacers GS and the hardmask pattern MP may be used as an etching mask to perform an etching process on the second stack pattern STP2 and the third stack pattern STP3. In the etching process, a portion of the second stack pattern STP2 may be removed to form a plurality of second stack patterns STP2 that are separated from each other, and a portion of the third stack pattern STP3 may be removed to form a plurality of third stack patterns STP3 that are separated from each other. The plurality of second stack patterns STP2 may be spaced apart from each other in the second direction D2. The plurality of third stack patterns STP3 may be spaced apart from each other in the second direction D2. The etching process may expand the opening op between the sacrificial patterns PP that are adjacent to each other. The opening op may further include an empty space that are formed by removing the portion of the second stack pattern STP2 and the portion of the third stack pattern STP3. For example, the opening op may further include an empty space between the second stack patterns STP2 that are adjacent to each other in the second direction D2 and an empty space between the third stack patterns STP3 that are adjacent to each other in the second direction D2. The opening op may expose sidewalls of the second stack pattern STP2, sidewalls of the third stack patterns STP3, and a top surface of an uppermost first active layer ACL1 of the first stack pattern STP1.

Referring to FIG. 7C, a sacrificial spacer 220 may be formed through the opening op. The sacrificial spacer 220 may conformally cover, overlap, or be on the sidewalls of the gate spacers GS, the sidewalls of the second stack patterns STP2, the sidewalls of the third stack patterns STP3, and the top surface of the uppermost first active layer ACL1 of the first stack pattern STP1, which sidewalls and top surface are exposed through the opening op.

A portion of the sacrificial spacer 220, a portion of the first stack pattern STP1, and a portion of the substrate 210 may be removed through the opening op. A portion of the first stack pattern STP1 may be removed to form a plurality of first stack patterns STP1 that are separated from each other. The plurality of first stack patterns STP1 may be spaced apart from each other in the second direction D2. The opening op may further include an empty space formed by removing the portion of the sacrificial spacer 220, the portion of the first stack pattern STP1, and the portion of the substrate 210. The opening op may expose a sidewall of the sacrificial spacer 220, sidewalls of the first stack patterns STP1, and a surface of the substrate 210. In some embodiments, a dry etching process may be performed to remove the portion of the sacrificial spacer 220, the portion of the first stack pattern STP1, and the portion of the substrate 210.

Referring to FIG. 7D, a preliminary lower source/drain pattern pLSD may be formed which include a first preliminary semiconductor layer pSD1 and a second preliminary semiconductor layer pSD2. For example, a first selective epitaxial growth process may be performed in which the exposed sidewall of the first stack pattern STP1 and the exposed surface of the substrate 210 are used as a seed to form the second preliminary semiconductor layer pSD2. For example, the first selective epitaxial growth process may include a chemical vapor deposition (CVD) process or a molecular beam epitaxy (MBE) process.

The second preliminary semiconductor layer pSD2 may undergo a second selective epitaxial growth process to form the first preliminary semiconductor layer pSD1.

The first and second preliminary semiconductor layers pSD1 and pSD2 may include a semiconductor material. A concentration of the semiconductor material included in the second preliminary semiconductor layer pSD2 may be less than a concentration of the semiconductor material included in the first preliminary semiconductor layer pSD1. For example, the first preliminary semiconductor layer pSD1 and the second preliminary semiconductor layer pSD2 may include silicon-germanium (SiGe), and compared to the first preliminary semiconductor layer pSD1, the second preliminary semiconductor layer pSD2 may include germanium (Ge) whose concentration is relatively low.

The first preliminary semiconductor layer pSD1 and the second preliminary semiconductor layer pSD2 may constitute the preliminary lower source/drain pattern pLSD. During the second selective epitaxial growth process, impurities may be in-situ implanted into the preliminary lower source/drain pattern pLSD. Alternatively, after the formation of the preliminary lower source/drain pattern pLSD, impurities may be implanted into the preliminary lower source/drain pattern pLSD. The preliminary lower source/drain pattern pLSD may be doped to have a first conductivity type (e.g., p-type).

The preliminary lower source/drain pattern pLSD may partially or completely fill a lower portion of the opening op. The preliminary lower source/drain pattern pLSD may cover, overlap, or be on the sidewalls of the first stack patterns STP1 and the surface of the substrate 210, which sidewalls and surface are exposed through the opening op. The preliminary lower source/drain pattern pLSD may include the first preliminary semiconductor layer pSD1 and the second preliminary semiconductor layer pSD2. The first preliminary semiconductor layer pSD1 may be formed on the sidewalls of the first stack patterns STP1 and the surface of the substrate 210, which sidewalls and surface are exposed through the opening op. The second preliminary semiconductor layer pSD2 may be formed on the first preliminary semiconductor layer pSD1. The opening op may expose a top surface of the second preliminary semiconductor layer pSD2.

Referring to FIG. 7E, the sacrificial spacer 220 may be removed. The sacrificial spacer 220 may be removed to expose the sidewalls of the second stack patterns STP2 and the sidewalls of the third stack patterns STP3. In some embodiments, the sacrificial spacer 220 may be removed through a wet etching process.

A first interlayer dielectric layer 140 and a second interlayer dielectric layer 150 may be formed. A lower portion of the opening op may be filled with the first interlayer dielectric layer 140 and the second interlayer dielectric layer 150. The first interlayer dielectric layer 140 may be formed on the preliminary lower source/drain patterns pLSD. The first interlayer dielectric layer 140 may conformally cover the exposed sidewalls of the second stack patterns STP2 and the exposed top surfaces of the preliminary lower source/drain patterns pLSD. The second interlayer dielectric layer 150 may be formed on the first interlayer dielectric layer 140.

Upper source/drain patterns USD may be formed on the first interlayer dielectric layer 140 and the second interlayer dielectric layer 150. For example, a third selective epitaxial growth process may be performed in which a sidewall of the third stack pattern STP3 is used as a seed to form the upper source/drain pattern USD. The upper source/drain pattern USD may be doped to have a second conductivity type (e.g., n-type) different from the first conductivity type. A portion of the opening op may be filled with the upper source/drain pattern USD. The upper source/drain pattern USD may be in contact with the sidewalls of the third stack patterns STP3.

The first active layers ACL1, the second active layers ACL2, and the third active layers ACL3 may be formed into semiconductor patterns SP. The semiconductor patterns SP may be interposed between a pair of neighboring preliminary lower source/drain patterns pLSD and between a pair of neighboring upper source/drain patterns USD. A channel structure CH may be constituted by the semiconductor patterns SP interposed between the pair of preliminary lower source/drain patterns pLSD and between the pair of upper source/drain patterns USD.

Referring to FIG. 7F, a first upper dielectric layer 170 may be formed on the upper source/drain patterns USD. The first upper dielectric layer 170 may be planarized until a top surface of the sacrificial pattern PP is exposed. An etch-back process or a chemical mechanical polishing (CMP) process may be employed to planarize the first upper dielectric layer 170. During the planarization process, the hardmask pattern MP may all be removed. As a result, a top surface of the first upper dielectric layer 170 may be coplanar with that of the sacrificial pattern PP and those of the gate spacers GS.

The exposed sacrificial pattern PP may be selectively removed. The removal of the sacrificial pattern PP may include performing a wet etching process using an etchant that selectively etches polysilicon. The removal of the sacrificial pattern PP may expose the first, second, and third sacrificial layers SAL1, SAL2, and SAL3.

An etching process may be performed in which the first, second, and third sacrificial layers SAL1, SAL2, and SAL3 are selectively etched to remove only the first, second, and third sacrificial layers SAL1, SAL2, and SAL3 while leaving the semiconductor patterns SP. The etching process may have a higher etch rate with respect to silicon-germanium.

A gate dielectric layer GI may be conformally formed in a region where the sacrificial pattern PP and the first, second, and third sacrificial layers SAL1, SAL2, and SAL3 are removed. A gate electrode GE may be formed which includes a lower electrode LE, a middle electrode ME, and an upper electrode UE. The lower electrode LE may be formed on the gate dielectric layer GI between a pair of neighboring preliminary lower source/drain patterns pLSD. The middle electrode ME may be formed on the lower electrode LE. The upper electrode UE may be formed on the gate dielectric layer GI between a pair of neighboring upper source/drain patterns USD.

A gate capping pattern GP may be formed on the upper electrode UE. A first upper dielectric layer 170 may be additionally deposited on the gate capping pattern GP.

On the upper source/drain pattern USD, a portion of the first upper dielectric layer 170 may be removed. An upper contact dielectric layer FIL and a preliminary contact dielectric layer FSI may be formed on an empty space formed by removing the portion of the first upper dielectric layer 170. Therefore, the opening op may be completely filled with the upper contact dielectric layer FIL and the preliminary contact dielectric layer FSI.

Referring to FIG. 7G, an upper contact FSC may be formed. The preliminary contact dielectric layer FSI may be removed to form an empty space, and the empty space may be filled with a conductive material to form the upper contact FSC. In some embodiments, the preliminary contact dielectric layer FSI may be removed through a dry etching process.

A second upper dielectric layer 180 may be formed on the first upper dielectric layer 170. Upper vias UV may be formed in the second upper dielectric layer 180. A third upper dielectric layer 190 may be formed on the second upper dielectric layer 180. Upper signal lines US may be formed in the third upper dielectric layer 190.

Referring to FIG. 7H, the substrate 210 may be overturned to expose a rear surface of the substrate 210. The exposed substrate 210 may be removed. The removal of the substrate 210 may expose the gate dielectric layer GI and the second preliminary semiconductor layer pSD2 of the preliminary lower source/drain pattern pLSD. The exposed portion of the second preliminary semiconductor layer pSD2 may be removed. The partial removal of the second preliminary semiconductor layer pSD2 may form a second semiconductor layer SD2. The second preliminary semiconductor layer pSD2 that remains after partial removal may be defined as the second semiconductor layer SD2. A portion of the second preliminary semiconductor layer pSD2 may be removed to expose the first preliminary semiconductor layer pSD1. In some embodiments, a portion of the second preliminary semiconductor layer pSD2 and the substrate 210 may be removed by a chemical mechanical polishing process or a wet etching process.

The second preliminary semiconductor layer pSD2 may have an etch selectivity with respect to the first preliminary semiconductor layer pSD1. For example, in the etching process, a portion of the second preliminary semiconductor layer pSD2 may be removed, and the first preliminary semiconductor layer pSD1 may not be removed.

Referring to FIG. 7I, a third lower dielectric layer 130 may be formed. The third lower dielectric layer 130 may cover, overlap, or be on the gate dielectric layer GI and the preliminary lower source/drain patterns pLSD. A portion of the third lower dielectric layer 130 may be removed to expose a surface of each of the preliminary lower source/drain patterns pLSD. In some embodiments, the portion of the third lower dielectric layer 130 may be removed through a chemical mechanical polishing process. As a result, a top surface of the third lower dielectric layer 130 may be coplanar with the surface of each of the preliminary lower source/drain patterns pLSD.

Referring to FIG. 7J, a portion of each of the first preliminary semiconductor layers pSD1 may be removed. The removal of the first preliminary semiconductor layer pSD1 may form a first semiconductor layer SD1. The first preliminary semiconductor layer pSD1 that remains after partial removal may be defined as the first semiconductor layer SD1. The formation of the first semiconductor layer SD1 may define a lower source/drain pattern LSD. In some embodiments, a portion of the first preliminary semiconductor layer pSD1 may be removed through a dry etching process or a wet etching process.

Referring to FIG. 7K, lower contact dielectric layers BIL and lower contacts BSC may be formed. The lower contact dielectric layer BIL and the lower contact BSC may be formed by allowing a dielectric material and a conductive material to fill an empty space formed by removing the first preliminary semiconductor layer pSD1.

Referring back to FIG. 4, a first lower dielectric layer 110 and a second lower dielectric layer 120 may be formed. The second lower dielectric layer 120 may be formed on the third lower dielectric layer 130. The first lower dielectric layer 110 may be formed on the second lower dielectric layer 120. Lower vias LV may be formed in the second lower dielectric layer 120. Lower signal lines LS may be formed in the third lower dielectric layer 130. A semiconductor device may be overturned to allow the lower source/drain pattern LSD to rest beneath the upper source/drain pattern USD.

In a semiconductor device according to some embodiments of the present inventive concepts, a lower source/drain pattern may include a first semiconductor layer that vertically extends. It may thus be possible to omit the formation of a spacer in the procedure for forming the lower source/drain pattern. Accordingly, there may be a reduction in the difficulty and number of process steps in fabricating the semiconductor device.

In a semiconductor device according to some embodiments of the present inventive concepts, a lower source/drain pattern may include a first semiconductor layer that vertically extends. Therefore, a volume of the lower source/drain pattern may increase to improve electrical properties of the semiconductor device.

Although the present invention has been described in connection with some embodiments of the present inventive concepts illustrated in the accompanying drawings, it will be understood by one of ordinary skill in the art that variations in form and detail may be made therein without departing from the spirit and described features of the present inventive concepts. The above disclosed embodiments should thus be considered illustrative and not restrictive.

What is claimed is:

1. A semiconductor device, comprising:
a first channel structure that extends in a first direction;
a second channel structure that extends in the first direction and is adjacent in a second direction to the first channel structure, the second direction intersecting the first direction;
a source/drain structure between the first channel structure and the second channel structure, wherein the source/drain structure includes a lower source/drain pattern and an upper source/drain pattern that overlaps in a third direction with the lower source/drain pattern, the third direction intersecting the first direction and the second direction; and
a lower contact that is in contact with the lower source/drain pattern,
wherein the lower source/drain pattern comprises:
a first semiconductor layer; and
a second semiconductor layer in contact with the first semiconductor layer,
wherein the first semiconductor layer comprises:
a sidewall in contact with the second semiconductor layer;
a contact surface that is in contact with the lower contact; and
a bottom surface that extends from the sidewall to the contact surface,
wherein the sidewall of the first semiconductor layer comprises:
a first portion in contact with the second semiconductor layer; and
a second portion spaced apart in the third direction from the second semiconductor layer.

2. The semiconductor device of claim 1, wherein a minimum distance between the contact surface and a top surface of the first semiconductor layer is less than a minimum distance between the bottom surface of the first semiconductor layer and the top surface of the first semiconductor layer.

3. The semiconductor device of claim 1, wherein the bottom surface of the first semiconductor layer is planar.

4. The semiconductor device of claim 1, further comprising:
a lower dielectric layer that extends around the lower contact and the lower source/drain pattern in plan view,
wherein the second portion of the first semiconductor layer is in contact with the lower dielectric layer.

5. The semiconductor device of claim 1, wherein the second semiconductor layer is spaced apart from the lower contact in the third direction.

6. The semiconductor device of claim 5, further comprising:
a lower contact dielectric layer that extends around the lower contact in plan view,
wherein the bottom surface of the first semiconductor layer is in contact with the lower contact dielectric layer.

7. The semiconductor device of claim 1, wherein a distance from an uppermost portion of the lower contact to an upper surface of the lower source/drain pattern is less than a distance from the bottom surface of the first semiconductor layer to the upper surface of the lower source/drain pattern.

8. The semiconductor device of claim 1, wherein the second semiconductor layer comprises:
a bottom surface; and
an inclined surface that intersects the bottom surface at an oblique angle.

9. The semiconductor device of claim 8, wherein the bottom surface and the inclined surface of the second semiconductor layer are both planar.

10. The semiconductor device of claim 8, wherein a distance from the bottom surface of the second semiconductor layer to an upper surface of the lower source/drain pattern is less than a distance from the contact surface of the first semiconductor layer to the upper surface of the lower source/drain pattern.

11. The semiconductor device of claim 8, further comprising:
a gate electrode that overlaps in the third direction with the first channel structure; and
a gate dielectric layer that extends around the gate electrode in plan view,
wherein a distance from the bottom surface of the second semiconductor layer to an upper surface of the lower source/drain pattern is greater than a distance from a lowermost portion of the gate dielectric layer to the upper surface of the lower source/drain pattern.

12. The semiconductor device of claim 1, wherein the first semiconductor layer comprises:
a lower pattern; and
an upper pattern on the lower pattern,
wherein the lower pattern is spaced apart from the second semiconductor layer in the third direction, and
wherein the upper pattern is in contact with the second semiconductor layer.

13. The semiconductor device of claim 12, wherein a distance from a bottom surface of the lower pattern of the first semiconductor layer to an upper surface of the lower source/drain pattern is greater than a distance from a lower surface of the second semiconductor layer to the upper surface of the lower source/drain pattern.

14. A semiconductor device, comprising:
a first channel structure that extends in a first direction;
a second channel structure that extends in the first direction and is adjacent in a second direction to the first channel structure, the second direction intersecting the first direction;
a source/drain structure between the first channel structure and the second channel structure, wherein the source/drain structure includes a lower source/drain pattern and an upper source/drain pattern that overlaps in a third direction with the lower source/drain pattern, the third direction intersecting the first direction and the second direction; and
a lower contact that is in contact with the lower source/drain pattern,
wherein the lower source/drain pattern comprises:
a first semiconductor layer; and
a second semiconductor layer that is in contact with the first semiconductor layer,
wherein a distance from a lowermost portion of the first semiconductor layer to an upper surface of the lower source/drain pattern is greater than a distance from a lowermost portion of the second semiconductor layer to the upper surface of the lower source/drain pattern.

15. The semiconductor device of claim 14, wherein a distance from an uppermost portion of the lower contact to the upper surface of the lower source/drain pattern is greater than a distance from the lowermost portion of the second semiconductor layer to the upper surface of the lower source/drain pattern.

16. The semiconductor device of claim 15, further comprising:
a lower contact dielectric layer that extends around the lower contact in plan view,
wherein the first semiconductor layer comprises:
a contact surface that is in contact with the lower contact; and
a bottom surface in contact with the lower contact dielectric layer.

17. The semiconductor device of claim 14, further comprising:
a gate electrode that overlaps in the third direction with the first channel structure; and
a gate dielectric layer that extends around the gate electrode in plan view,
wherein the distance from the lowermost portion of the first semiconductor layer to the upper surface of the lower source/drain pattern is greater than a distance from a lowermost portion of the gate dielectric layer to the upper surface of the lower source/drain pattern.

18. The semiconductor device of claim 17, wherein the distance from an uppermost portion of the lower contact to the upper surface of the lower source/drain pattern is greater than the distance from the lowermost portion of the gate dielectric layer to the upper surface of the lower source/drain pattern.

19. A semiconductor device, comprising:
a lower dielectric layer;
a first channel structure that extends in a first direction on the lower dielectric layer;
a second channel structure that extends in the first direction and is adjacent in a second direction to the first channel structure, the second direction intersecting the first direction;
a first gate electrode that overlaps in a third direction with the first channel structure, the third direction intersecting the first direction and the second direction;
a second gate electrode that overlaps in the third direction with the second channel structure;
a lower source/drain pattern between the first channel structure and the second channel structure;
an upper source/drain pattern that overlaps in the third direction with the lower source/drain pattern;
a lower contact that extends into the lower dielectric layer to electrically connect to the lower source/drain pattern; and
an upper contact electrically connected to the upper source/drain pattern,
wherein the lower source/drain pattern comprises:
a first semiconductor layer; and
a second semiconductor layer in contact with the first semiconductor layer,
wherein the first semiconductor layer comprises:
an upper pattern in contact with the second semiconductor layer; and
a lower pattern in contact with the lower contact,
wherein the lower pattern of the first semiconductor layer is spaced apart in the third direction from the second semiconductor layer and is between the upper pattern and the lower contact.

20. The semiconductor device of claim 19, wherein the lower pattern is in contact with the lower dielectric layer.
